(19) United States
(12) Patent Application Publication
(10) Pub. No.: US 2026/0016543 A1
(43) Pub. Date: Jan. 15, 2026

(54) CURRENT MONITORING MODULE, SYSTEM, AND ELECTRIC VEHICLE

(71) Applicant: HELLA GMBH & CO. KGAA, Lippstadt (DE)

(72) Inventors: Francesco Canicatti, Erwitte (DE); Melanie Loebel, Lippstadt (DE); Thomas Paeschke, Berlin (DE)

(21) Appl. No.: 19/263,903

(22) Filed: Jul. 9, 2025

(30) Foreign Application Priority Data
Jul. 10, 2024 (DE) 102024119571.1

(51) Int. Cl. G01R 31/382; B60L 3/12; B60L 58/10

(52) U.S. Cl. CPC G01R 31/382; B60L 3/12; B60L 58/10

(57) ABSTRACT

The invention relates to a current monitoring module for measuring current flows within an electric vehicle. The current monitoring module includes: at least two shunt modules, each with a defined resistor for measuring the respective current flows, wherein each shunt module is arranged in a separate current path; at least two communication interfaces for reading out the respective measured current flow of each shunt module; at least one circuit board for arranging the at least two shunt modules; wherein the at least one circuit board and the respective resistances of the at least two shunt modules are arranged within a single housing for electrical insulation. The invention further relates to a system and an electric vehicle.

### CROSS-REFERENCE TO RELATED APPLICATIONS

The present application claims the benefit of German Patent Application No. 10-2024-119-571.1, filed Jul. 10, 2024, the disclosure of which is incorporated by reference.

### FIELD OF THE INVENTION

The invention relates to a current monitoring module for measuring current flows within an electric vehicle, a system, and an electric vehicle.

### BACKGROUND OF THE INVENTION

Current monitoring modules are suitable for measuring an applied electrical voltage in a circuit, for example, and thus determining the current flow. Information about the level of voltage applied is particularly important for detecting and avoiding current and voltage peaks. Information about the voltage applied can also be used to utilize electrical components in the circuit as efficiently as possible. Current monitoring modules are used in electric vehicles in particular to provide information about the state of charge of the high-voltage battery. Shunts, also known as shunt modules, with defined resistors can be used to measure current flows within the electric vehicle. The defined resistor within a shunt causes a voltage drop, which can be used to determine a current flow. Electric vehicles, in particular electric cars, are often based on a 400 V voltage grid or a 400 V architecture. However, it has been found that increasing the voltage from 400 V to 800 V can significantly reduce charging times and at the same time achieve a considerable reduction in the weight of the battery and thus of the electric vehicle. For example, in order to measure a voltage of 800 V, two 400 V current monitoring modules are required. However, the installation of two modules increases the overall weight of the vehicle and requires additional space.

It is therefore an object of the present invention to at least partially overcome at least one of the disadvantages described above. In particular, it is the object of the invention to provide a particularly compact, weight-reduced and cost-effective current monitoring module, a system with a current monitoring module and an electric vehicle which ensures precise and reliable measurement of the current flows in an electric vehicle.

### SUMMARY OF THE INVENTION

The above object is achieved by a current monitoring module, a system, and an electric vehicle in accordance with embodiments of the invention. Features and details described in connection with the current monitoring module according to the invention of course also apply in connection with the system according to the invention and/or in connection with the electric vehicle according to the invention and vice versa, so that with regard to the disclosure reference is or can always be made reciprocally to the individual aspects of the invention.

According to a first aspect of the invention, a current monitoring module for measuring current flows within an electric vehicle is provided, the current monitoring module comprising: at least two shunt modules, each with a defined resistor for measuring the respective current flows, wherein each shunt module is arranged in a separate current path; at least two communication interfaces for reading out the respective measured current flow of each shunt module; at least one circuit board for arranging the at least two shunt modules, wherein the at least one circuit board and the respective resistors of the at least two shunt modules are arranged within a single housing for electrical insulation.

Preferably, the current monitoring module is used to determine the current flow within an electric vehicle, in particular from and/or to a battery. An electric vehicle can be understood as, for example, an electrically powered car or an electrically powered truck. A shunt module can preferably be understood as an elongated component, in particular a rail, preferably made of metal. The shunt module can have an attachment point at each end of the elongated component, via which the shunt module can be integrated into an electrical circuit. In particular, the attachment point of the shunt module can comprise a passage via which the shunt module can be integrated into the circuit, preferably by means of connectors, terminals, soldering or welding. A defined resistor is provided between the two attachment points of the shunt module, preferably comprising one of the following alloys: manganin, constantan, nichrome, isotan, and/or isabellin. Furthermore, the defined resistor can comprise pure copper. The resistor is preferably of low resistance and in particular has a resistance of 50 μΩ to 500 μΩ, which leads to a voltage drop. The voltage drop upstream and/or downstream of the defined resistor can be determined using a measuring device, in particular measuring pins, which are preferably arranged on the circuit board. In particular, the current monitoring module according to the invention has two shunt modules, each of which is arranged in a different current path. This can, for example, enable two shunt modules designed for a 400 V architecture to be combined and used in particular in an 800 V voltage network. A current path can be understood in particular as the path that an electric current takes through a circuitry or a system. Within the meaning of the present subject matter of the invention, this can be understood to mean that the at least two shunt modules measure the respective current flow of two different current paths.

Furthermore, according to the invention, two communication interfaces are provided for reading out the respective measured current flow of each shunt module. Within the scope of the invention, the current flow measured at a respective shunt module can preferably be read out using a respectively assigned communication interface. In other words, the communication interface can be suitable for outputting the detected current flow of an assigned shunt module. A communication interface can be understood as a connector or a wireless connection.

Furthermore, at least one circuit board is provided for arranging the at least two shunt modules. Within the meaning of the present subject matter of the invention, a circuit board can be understood to be a board or a printed circuit board. According to the invention, if only one circuit board is present, two shunt modules can be attached to the circuit board and, if two or more circuit boards are present, one shunt module can be attached to each respective circuit board. In particular, it may also be possible to provide more than two circuit boards in a current monitoring module and/or to provide more than two shunt modules per circuit board. Furthermore, the circuit board can be designed to have conductor paths for electrical current, in particular signals.

The at least one circuit board and the respective resistors of the at least two shunt modules are arranged within a single housing for electrical insulation. In other words, the at least two shunt modules are enclosed, at least in certain areas, by a single housing, which also encloses the at least one circuit board and the respective resistors. Accordingly, it may also be provided within the scope of the invention that, in particular, more than one circuit board and, in particular, more than two shunt modules are arranged at least in certain areas in a single housing. At least in certain areas means that only the connections of the respective shunt modules are arranged outside the housing. The housing can electrically insulate the at least partially enclosed components from one another. The housing can be designed in such a way that at least the circuit board can be attached to and/or in the housing. The housing can preferably be designed to be fluid-tight. In particular, the housing can be designed to be so resistant that at least the circuit board is protected against mechanical shocks and vibrations.

The current monitoring module according to the invention provides a particularly compact, weight-reduced and cost-effective current monitoring module that ensures precise and reliable measurement of the current flows in an electric vehicle. In particular, such a current monitoring module can either save installation space in a vehicle or create installation space that can be used for other purposes, for example by a larger battery module. The fact that, according to the invention, a plurality of shunt modules are accommodated in a single housing makes it much easier to install the single current monitoring module within the vehicle. The connection of the respective current paths is also facilitated, as they are all connected to the respective shunt modules at almost the same point, namely on the single housing of the current monitoring module. In particular, this significantly reduces installation times compared to conventional power consumption modules.

Within the scope of the invention, it may be advantageous for the at least two shunt modules to be arranged at a distance from one another within the housing for electrical insulation, the distance preferably being at least 1 mm to 10 mm, particularly preferably 2 mm and 5 mm. The at least two shunt modules can preferably be arranged on a common circuit board or on a respective circuit board. In particular, it may be provided that each shunt module is arranged on a separate circuit board. By spacing the at least two shunt modules apart, the advantage can be achieved that unwanted transmissions of electrical potentials between the electrical components are avoided and thus a particularly reliable measurement of current flows within an electric vehicle can be achieved by the current monitoring module.

Within the scope of the invention, it may be provided in a current monitoring module that an insulating means is provided for electrically isolating the at least two shunt modules from one another, wherein the insulating means comprises in particular at least one of the components epoxy resin, silicone or air. If the insulating means comprises air, for example, at least one insulating slot can be arranged on the at least one circuit board and/or an air gap for separating electrical lines can be arranged between at least two circuit boards. Furthermore, silicone seals and/or epoxy resin seals can be arranged on the at least one circuit board or can be arranged between at least two circuit boards. The advantage of using an insulating means within the scope of the present invention is that no electrical potentials can be transmitted between the shunt modules, so that a particularly reliable measurement of the current flows can be ensured by the current monitoring module. Furthermore, short circuits can be prevented and the heat distribution within the current monitoring module can be controlled very well.

Within the scope of the invention, it may be provided in a current monitoring module that each communication interface is designed as a connector, in particular on a circuit board or on a respective circuit board. Preferably, a connector for reading out the respective measured current flow can be provided for each shunt module, wherein the connectors are connected to the respective shunt modules in particular via electrical lines, in particular cable connections. In particular, the connections can be arranged on the circuit board. The connectors can be connected wired or wirelessly to an evaluation unit for evaluating the current flows detected by measuring devices. In particular, the evaluation unit may be arranged on the one circuit board, on one of the plurality of circuit boards or outside of the current monitoring module. The advantage of using a connector according to the invention is the particularly reliable detection of measured current flows. Furthermore, connectors enable the modular design of communication systems, allowing different components to be easily connected and exchanged. It is particular advantageous that the current monitoring module according to the invention may require only a single evaluation unit, compared to current monitoring modules that only have a shunt module. In particular, this can save costs.

It is also conceivable in a current monitoring module that the at least two shunt modules are arranged on a common circuit board, with an insulating means being arranged on the circuit board between the respective shunt modules. The insulating means may preferably comprise at least one of the components epoxy resin, silicone or air. For example, insulating slots for separating electrical lines and/or silicone seals and/or epoxy resin seals can be arranged on the common circuit board between the respective shunt modules. The advantage of a common circuit board for the at least two shunt modules is the particularly compact and space-saving design of the current monitoring module. Furthermore, the installation and maintenance of the current monitoring module can be facilitated as a compact component contains the various components to be maintained and connections between the components on the circuit board can be clearly marked and defined.

It may also be provided in a current monitoring module that at least two circuit boards are provided, each circuit board having a shunt module, with adjacent circuit boards being arranged spaced apart from one another. Advantageously, it may be provided that an insulating means is arranged between two circuit boards, which in particular can comprise at least one of the components epoxy resin, silicone or air. For example, an air gap and/or a silicone seal and/or an epoxy resin seal can be arranged between two adjacent circuit boards. The advantage of using two circuit boards within the meaning of the invention is that electrical insulation of the shunt modules, each arranged on one of the circuit boards, is made possible, wherein an unwanted transmission of electrical potentials between the shunt modules in the one single housing can be avoided. Thus, a reliable and precise measurement of the current flows by the current monitoring module can be realized.

Furthermore, within the scope of the invention, it may be provided for a current monitoring module that, for each circuit board, the respective shunt module and the respective communication interface are arranged at the same predefined positions. The respective communication interface and the respective shunt module can preferably be attached to the circuit board at predefined distances. In particular, marked areas of the circuit board can represent the predefined positions of the respective shunt module and the respective communication interface. In other words, the respective circuit boards can be regarded as identical units in which the components, such as the respective shunt module and/or the respective communication interface and/or an evaluation unit on the circuit board, are arranged in a previously defined area. It may therefore be provided that all circuit boards are constructed identically. This has the advantage that the use of identical units with the identical predefined positions of the components facilitates the installation and maintenance of the current monitoring module. Furthermore, the installation costs or the installation effort of the current monitoring module can be reduced, enabling particularly cost-effective production within a system of a vehicle comprising a battery and such a current monitoring module, and thus of a vehicle.

With reference to the present invention, it is conceivable in a current monitoring module that the respective adjacent circuit boards are arranged with the same orientation within the one housing. It may therefore be provided that the at least two identically constructed circuit boards are aligned identically within one housing. This can have the advantage of saving time in the manufacturing process by allowing the same unit to be arranged on the circuit board with the same orientation. This means that the robotics can only perform a single motion sequence, saving costs and installation time.

Furthermore, in a current monitoring module, it is conceivable that the respective adjacent circuit boards are arranged with different orientations within the one housing, with the respective adjacent circuit boards being rotated by 180 degrees, in particular in the horizontal plane. It may therefore be provided that the at least two circuit boards are aligned rotated by 180 degrees relative to one another within the one housing. This means that the respective communication interfaces can preferably be arranged on the respective adjacent circuit board on the same side within the housing. This has the advantage that the readout data of the communication interfaces can be taken from one side of the housing, reducing the amount of cabling required and thus saving space. The installation of wired connections to the connectors is also significantly easier, as only a single current monitoring module is required.

According to a second aspect of the invention, the above object is further achieved by a system according to the invention, comprising a battery of an electric vehicle and a current monitoring module according to the first aspect of the invention.

This results in the same advantages with respect to a system according to the invention as have already been described with respect to a current monitoring module according to the invention according to the first aspect.

According to a third aspect of the invention, the above object is further achieved by an electric vehicle according to the invention, comprising a system according to the second aspect of the invention.

This results in the same advantages with respect to an electric vehicle according to the invention as have already been described with respect to a current monitoring module and/or a system according to the invention.

Further advantages, features and details of the invention are apparent from the following description, in which several embodiment examples of the invention are described in detail with reference to the drawings. Here, the features mentioned in the claims and in the description can each be essential to the invention individually or in any combination.

### BRIEF DESCRIPTION OF THE DRAWING

The invention is explained in more detail below with reference to the accompanying drawings. In the figures:

FIG. 1 is a current monitoring module with two shunt modules on a common circuit board;

FIG. 2 is a current monitoring module with two identically aligned circuit boards and a shunt module arranged on each circuit board;

FIG. 3 is a current monitoring module with two oppositely aligned circuit boards and a shunt module arranged on each circuit board;

FIG. 4 is a system with a battery and a current monitoring module; and

FIG. 5 is an electric vehicle comprising a current monitoring module.

### DETAILED DESCRIPTION OF THE CURRENT EMBODIMENT

In the following figures, the same technical features, including those of different embodiment examples, are represented by identical reference signs.

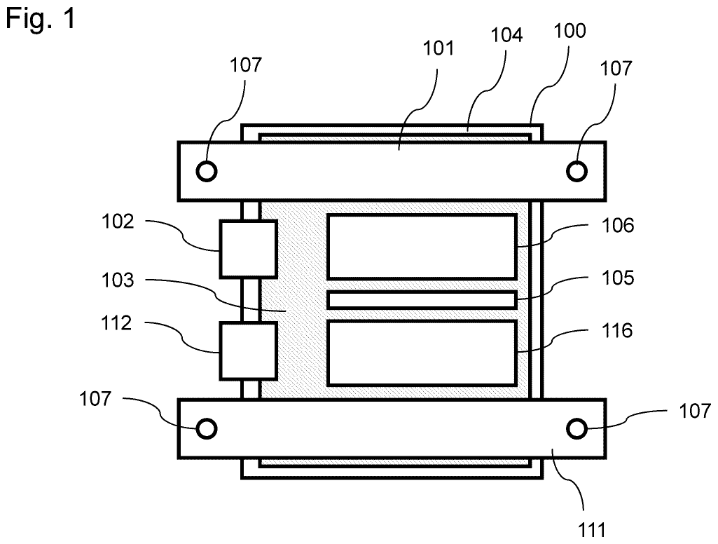

FIG. 1 shows a current monitoring module 100 comprising two shunt modules 101, 111 arranged on a common circuit board 103, with at least the circuit board 103 being arranged at least partially within a single housing 104. The shunt modules 101, 111 are arranged at the edge of the circuit board 103. However, it may also be provided that the shunt modules 101, 111 occupy any other position on the circuit board 103, in particular such that the shunt modules 101, 111 are not in contact with one another. Two communication interfaces 102, 112, in particular connectors, and two evaluation units 106, 116 are arranged between the two shunt modules 101, 111. Preferably, each shunt module 101, 111 can be assigned a connector 102, 112 and an evaluation unit 106, 116. Each shunt module 101, 111 can have an attachment point 107 at both ends of the elongated component, via which each shunt module 101, 111 can be integrated into a circuit. In particular, the attachment point 107 of each shunt module 101, 111 can comprise a passage via which the respective shunt module 101, 111 can be integrated into the electrical circuit, preferably by means of connectors, terminals, soldering or welding. In particular, the communication interface 102, 112 can be connected directly to the respective shunt module 101, 111 via an electrical line, or can be connected to a respective evaluation unit 106, 116, which is connected to the respective shunt module 101, 111. The communication interfaces 102, 112 may be implemented as wired or wireless communication interfaces 102, 112. Each shunt module 101, 111 may have at least one resistor, in particular a low-resistance resistor. The at least one resistor can cause a voltage dip, which can then be read out via the corresponding evaluation unit 106, 116 and the communication interfaces 102, 112 or directly via the communication interfaces 102, 112. In particular, a shunt module 101, 111 may also have a plurality of resistors. The evaluation units 106, 116 can evaluate the result of each resistor and determine the current flow. An insulating means 105 may also be provided on the circuit board 103. The insulating means 105 may preferably comprise at least one of the components epoxy resin, silicone, or air. In particular, the shunt modules 101, 111, the evaluation units 106, 116, the communication interfaces 102, 112 and the insulating means 105 may occupy any position on the circuit board 103, in particular non-symmetrically. The at least one circuit board 103 and the respective resistors of the at least two shunt modules 101, 111 for electrical insulation may be arranged at least partially within the single housing 104. In other words, the aforementioned parts may all be at least partially enclosed within a single housing 104.

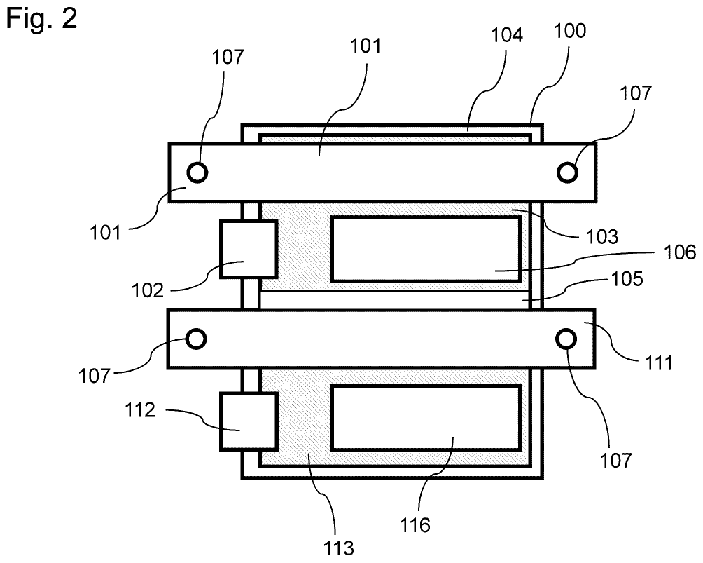

FIG. 2 depicts a current monitoring module 100 with two shunt modules 101, 111, each on a circuit board 103, 113. Both shunt modules 101, 111 are separated by an insulating means 105, in particular air. A shunt module 101, 111, an evaluation unit 106, 116 and a communication interface 102, 112 are each arranged on a circuit board 103, 113, the positions of the parts on the circuit boards 103, 113 being identical. The two circuit boards 103, 113, comprising a shunt module 101, 111, a communication interface 102, 112 and an evaluation unit 106, 116, may be an identically constructed circuit board 103 or an identical part. At least two identically constructed circuit boards 103, 113 may be arranged in the one housing 104, wherein the orientation of the identical parts may be identical. With regard to the present invention, it is therefore conceivable that the at least two identically constructed circuit boards 103 are aligned identically within the one housing 104. This can have the advantage of saving time in the manufacturing process by allowing the same unit to be arranged on the circuit boards 103, 113 with the same orientation.

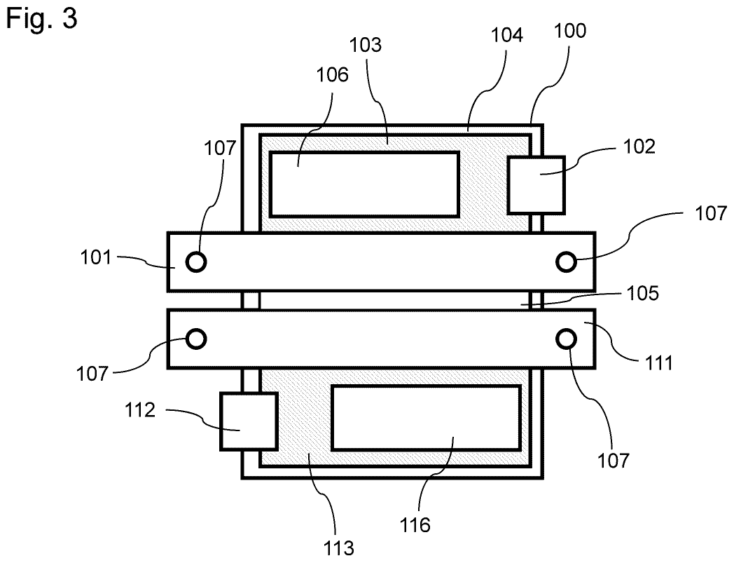

FIG. 3 shows a current monitoring module 100 with two shunt modules 101, 111 each on a circuit board 103, 113, although the identically constructed circuit boards 103, 113 are rotated by 180 degrees in the horizontal plane. In other words, two equal sides are adjacent to one another. It may therefore be provided that the at least two circuit boards 103, 113 are aligned rotated by 180 degrees relative to one another within the one housing 104. This means that the respective communication interfaces 102, 112 can preferably be arranged on the respective adjacent circuit board 103, 113 on the same side within the housing 104.

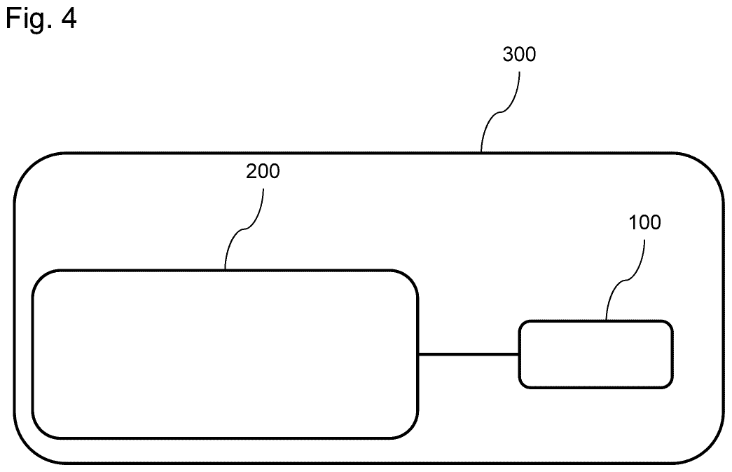

FIG. 4 shows a system 300 comprising a current monitoring module 100 according to the invention and a battery 200. In particular, the battery 200 can be a high-voltage battery for a vehicle.

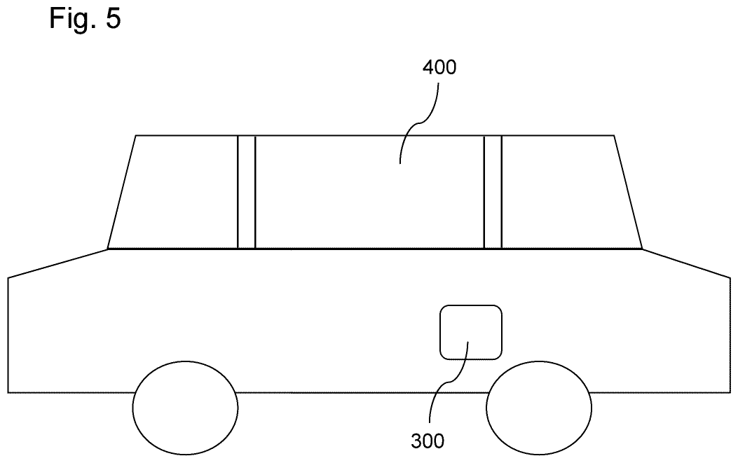

FIG. 5 depicts an electric vehicle 400 with a system 300 according to the invention.

### LIST OF REFERENCE SIGNS

100 current monitoring module
101 shunt module
102 communication interface
103 circuit board
104 housing
105 insulating means
106 evaluation unit
107 starting point
111 shunt module
112 communication interface
113 circuit board
116 evaluation unit
200 battery
300 system
400 electric vehicle

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A current monitoring module for measuring current flows within an electric vehicle, comprising:
at least two shunt modules, each with a resistor for measuring a respective current flow, wherein each shunt module is arranged in a separate current path;
at least two communication interfaces for reading out the respective measured current flow of each shunt module;
at least one circuit board for arranging the at least two shunt modules, wherein the at least one circuit board and the respective resistors of the at least two shunt modules are arranged within a single housing for electrical insulation.

2. The current monitoring module of claim 1, wherein the at least two shunt modules are spaced apart from one another within the housing for electrical insulation, wherein the spacing is between 1 mm and 10 mm.

3. The current monitoring module of claim 2, wherein an insulating means electrically insulates the at least two shunt modules from one another, wherein the insulating means comprises at least one of an epoxy resin, silicone, or air.

4. The current monitoring module of claim 1, wherein each communication interface is configured as a connector on a circuit board.

5. The current monitoring module of claim 1, wherein the at least one circuit board is a single circuit board, wherein an insulating means is arranged on the single circuit board between the at least two shunt modules.

6. The current monitoring module of claim 1, wherein the at least one circuit board includes first and second circuit boards, wherein each of the first and second circuit boards has at least one of the at least two shunt modules, wherein the first and second circuit boards are spaced apart from each other.

7. The current monitoring module of claim 6, wherein, for each of the first and second circuit boards, the respective shunt module and the respective communications interface are arranged at the same predefined positions on the respective first and second circuit boards.

8. The current monitoring module of claim 7, wherein the first and second circuit boards are arranged with the same orientation within the housing.

9. The current monitoring module of claim 7, wherein the first and second circuit boards are arranged with different orientations within the housing, being rotated by 180 degrees in a horizontal plane.

10. A system comprising:
a battery of an electric vehicle; and
the current monitoring module of claim 1.

11. An electric vehicle comprising the system of claim 10.
